(19) United States
(12) Patent Application Publication
(10) Pub. No.: US 2026/0148761 A1
(43) Pub. Date: May 28, 2026

(54) STACKED PNM DEVICE, AND CDC TRAINING METHOD AND NORMAL OPERATION METHOD OF STACKED PNM DEVICE

(71) Applicants: SK hynix Inc., Icheon-si (KR); SEOUL NATIONAL UNIVERSITY R&DB FOUNDATION, Seoul (KR)

(72) Inventors: Byung Kuk Yoon, Icheon-si (KR); Choung Ki Song, Icheon-si (KR); Jae Joon Kim, Seoul (KR); Sang Hyeok Han, Seoul (KR)

(21) Appl. No.: 19/063,722

(22) Filed: Feb. 26, 2025

(30) Foreign Application Priority Data
Nov. 28, 2024 (KR) 10-2024-0173336

(51) Int. Cl. G11C 11/4076; G11C 11/4093; G11C 11/4096

(52) U.S. Cl. CPC G11C 11/4076; G11C 11/4093; G11C 11/4096

(57) ABSTRACT

A stacked Processing Near Memory (PNM) device, in order to achieve smooth clock domain crossing (CDC) between a stacked memory chip and a logic chip and to minimize a consumption of die area, can train a delay time of an asynchronous path for each bank of the memory chip and optimally control an output timing of received data for each bank in each corresponding FIFO in consideration of the delay time of each bank as a result of the training. The stacked PNM device may perform a CDC training method and a normal operation method.

### CROSS-REFERENCE TO RELATED APPLICATION

This application claims priority under 35 U.S.C. § 119 to Korean Patent Application No. 10-2014-0173336 filed on Nov. 28, 2024, which is incorporated herein by reference in its entirety.

### BACKGROUND

### 1. Field

Illustrative embodiments relate to a processing near memory (PNM) device having a structure in which a memory layer and a processing layer are three-dimensionally stacked, and to a stacked PNM that provides smooth clock domain crossing (CDC) between a stacked DRAM chip and a logic chip and has a minimum consumption area; a CDC training process of the stacked PNM device; and a normal operation process of the stacked PNM device.

### 2. Discussion of the Related Art

Clock domain crossing (CDC) refers to data transmission and reception between different clock domains. Different clock domains include cases where the frequencies of signals used in respective domains are different, or where no synchronization based on a master clock is made in signal processing of a process in which data is output from one domain and another domain performs arithmetic calculation by using this data.

FIG. 1 illustrates an example of CDC.

An upper part of FIG. 1 shows a stacked DRAM chip DRAM DIE and a logic chip LOGIC DIE, and a lower part shows a timing diagram.

In response to a command COMP_RD generated in a control unit Ctrl Unit of the logic chip LOGIC DIE and received via a peripheral circuit PERI of the DRAM chip DRAM DIE, all or part of a process of outputting data stored in a bank BANK of the DRAM chip DRAM DIE to the logic chip Logic DIE is performed without using a clock signal CLK (Asynchronous), however, the clock signal CLK is used to perform a process (Synchronous) in which a PE array PE Array of the logic chip LOGIC DIE operates on data received from the DRAM chip DRAM DIE.

In the timing diagram, a read strobe signal RD_STROBE is a signal that is enabled at the moment when data is output from the DRAM chip DRAM DIE to indicate that the data is being output, a data signal RD_DATA refers to actual data output from the DRAM chip DRAM DIE, a FIFO output signal FOUT is a signal that controls the FIFO of the logic chip LOGIC DIE to output data to the PE array PE Array, and a process element input signal PE_INPUT refers to actual data applied from the FIFO of the logic chip LOGIC DIE to the PE array PE Array.

As illustrated in FIG. 1, when the DRAM chip DRAM DIE includes a plurality of banks and the logic chip LOGIC DIE includes a plurality of PE arrays, respective times (hereinafter, referred to as asynchronous delay values) which the banks between when the read strobe signal RD STROBE is asserted and the corresponding data is transmitted to the target PE array PE Array corresponding to each bank BANK may be different from each other due to variation in one or more of a chip manufacturing process, a voltage that is used, and a die temperature (i.e., process, voltage, and temperature (PVT)).

In the related art, in order to perform a function of transmitting, receiving, and storing data for safe CDC between the two chips DRAM DIE and LOGIC DIE, the depth of a FIFO used was increased to solve the problem. Increasing the depth of the FIFO means that the number of shift registers constituting the FIFO increases, which has the disadvantage of increasing a consumption of chip area.

### SUMMARY

Various embodiments are directed to providing a stacked processing near memory (PNM) device that, in order to achieve smooth cross domain crossing (CDC) between stacked DRAM chip DRAM DIE and logic chip LOGIC DIE and minimize a consumption of chip area, trains a delay time of an asynchronous path for each bank and controls an output timing of received data from a FIFO for each bank in consideration of the delay time of each bank determined as a result of the training.

Various embodiments are directed to providing a CDC training method of the stacked PNM device that in order to achieve smooth CDC between stacked DRAM chip DRAM DIE and logic chip LOGIC DIE and minimize a consumption area, can train a delay time of an asynchronous path for each bank and optimally control an output timing of received data for each bank in each FIFO in consideration of the delay time of each bank as a result of the training.

Various embodiments are directed to providing a normal operation method of the stacked PNM that in order to achieve smooth CDC between stacked DRAM chip DRAM DIE and logic chip LOGIC DIE and minimize a consumption area, can train a delay time of an asynchronous path for each bank and optimally control an output timing of received data for each bank in each FIFO in consideration of the delay time of each bank as a result of the training.

Technical problems to be solved in the present disclosure are not limited to the aforementioned technical problems and other unmentioned technical problems addressed by the present disclosure will be clearly understood by those skilled in the art from the following description.

A stacked PNM of the present disclosure may include: a DRAM chip including at least one bank configured to transmit stored data in response to a training read command and a read command; and a logic chip including a PE unit configured to receive the data from the DRAM chip and process the received data and a control unit configured to generate the training read command and the read command, the DRAM chip and the logic chip being stacked and electrically connected to each other, wherein the PE unit includes: a PE array including a plurality of processing elements; a FIFO configured to store the data received from the DRAM chip and transmit the stored data to the PE array in response to a FIFO output control signal; and a count unit configured to count a time for which data of the DRAM chip is transmitted to the FIFO for each bank, and the control unit includes: an offset corrector configured to generate an offset for each bank by using a count value output from the count unit; and a command generation unit including a command generator configured to generate the training read command during a training period and generate the read command during a normal operation period, and a command shifter configured to generate the FIFO output control signal by using the offset for each bank.

A CDC training method of a stacked PNM of the present disclosure may include: generating, by a control unit, a training read command and transmits the training read command to a DRAM chip including at least one bank; transmitting, by the DRAM chip, data stored in the bank to a PE unit in response to the training read command; counting, by a count unit constituting the PE unit, a transmission time for each bank; receiving, by an offset corrector constituting a control unit, the transmission time for each bank generated by the count unit and setting a reference transmission time; and setting, by the offset corrector, an offset value for each bank by using the reference transmission time.

An operation method of a stacked PNM of the present disclosure may include: generating, by a control unit, a read command and transmitting the read command to a DRAM chip including at least one bank; transmitting, by the DRAM chip, data stored in the plurality of banks to a PE unit constituting a logic chip in response to the read command; generating, by a command shifter, a FIFO output control signal for each bank by using a reference transmission time and an offset value for each bank received from an offset corrector; and transmitting, by a FIFO, data received from the bank to a PE array in response to the FIFO output control signal for each bank.

Technical problems to be achieved in the present disclosure are not limited to the aforementioned technical problems and the other unmentioned technical problems will be clearly understood by those skilled in the art from the following description.

A stacked PNM device, a CDC training method of the stacked PNM device, and a normal operation method of the stacked PNM device as described above according to the present disclosure can train a delay time of an asynchronous path for each bank and optimally control an output timing of received data for each bank in each corresponding FIFO in consideration of the delay time of each bank as a result of the training, in order to achieve smooth CDC between a stacked DRAM chip and a logic chip of the stacked PNM device and reduce a consumption of chip area.

Effects achievable in the disclosure are not limited to the aforementioned effects and the other unmentioned effects will be clearly understood by those skilled in the art from the following description.

### BRIEF DESCRIPTION OF THE DRAWINGS

FIG. 1 illustrates an example of CDC.

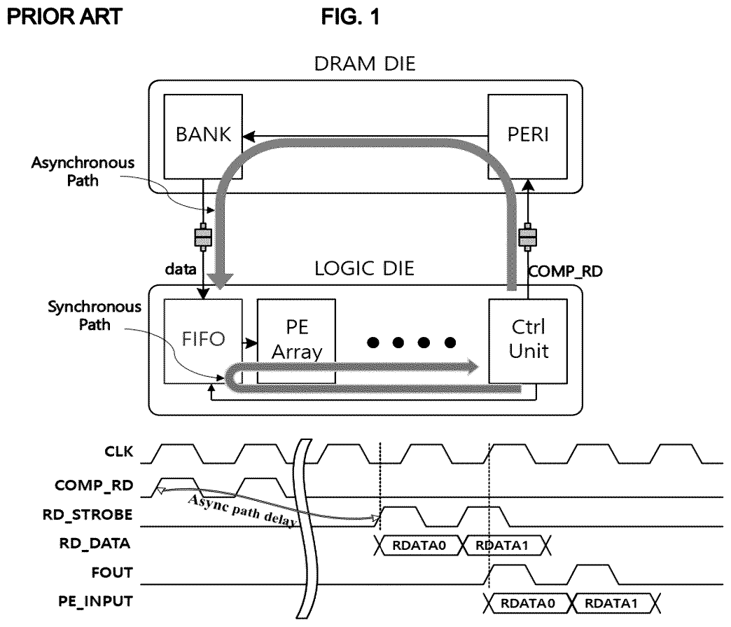

FIG. 2 illustrates an embodiment of a stacked PNM device according to the present disclosure.

FIG. 3 illustrates an internal configuration of a count unit, an offset corrector, and a command generation unit.

FIG. 4 illustrates a CDC training process of an embodiment of a stacked PNM device according to the present disclosure.

FIG. 5 illustrates an operating process of an embodiment of a stacked PNM device CDC according to the present disclosure.

FIG. 6 is a timing diagram of a stacked PNM device according to the present disclosure.

### DETAILED DESCRIPTION

In order to fully understand the present disclosure, advantages in operation of the present disclosure, and objects achieved by carrying out the present disclosure, the accompanying drawings for explaining illustrative examples of the present disclosure and the contents described with reference to the accompanying drawings may be referred to.

Hereinafter, the present disclosure is described in detail by describing illustrative embodiments of the present disclosure with reference to the accompanying drawings. The same reference numerals among the reference numerals in each drawing indicate the same members.

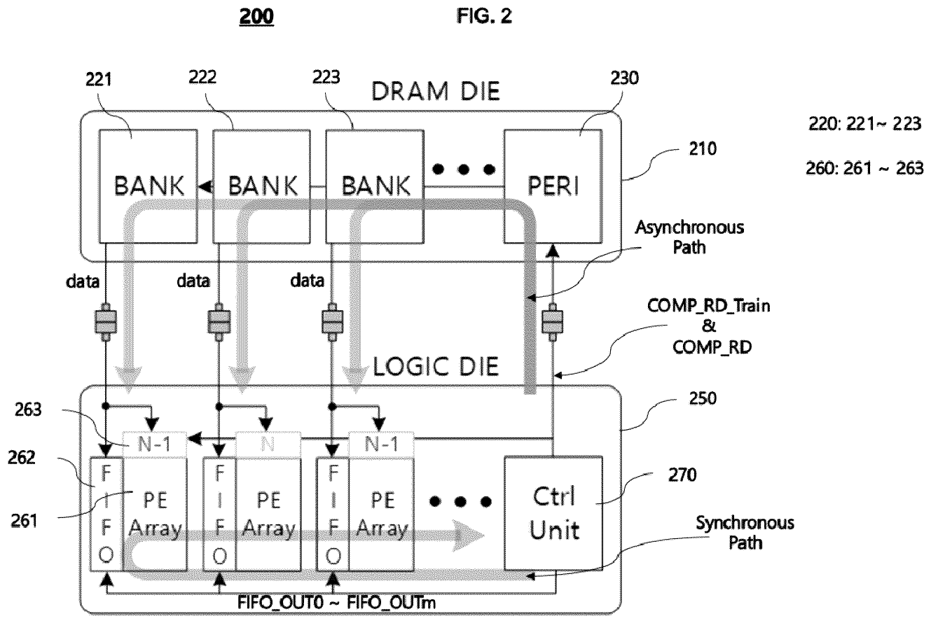

FIG. 2 illustrates an embodiment of a stacked PNM device 200 according to the present disclosure.

The PNM device 200 according to the present disclosure includes a stacked DRAM chip 210 and a logic chip 250.

The DRAM chip 210 includes a plurality of banks 220 (comprising banks 221 to 223 each including a respective plurality of memory cells storing data) and a peripheral circuit (PERI) 230 including various circuits for transmitting and receiving signals to/from an external device.

The logic chip 250 includes a PE unit 260 (comprising a PE array 261, a First-in-First-Out queue (FIFO) 262, and a count unit 263) and a control unit (Ctrl Unit) 270. As shown in FIG. 2, the logic chip 250 may include a plurality of instances of the PE unit 260.

The PE array 261 includes a plurality of processing elements (PEs) that process received data.

The FIFO 262 stores data received from the DRAM chip 210 and transmits the stored data to the PE array 261 in response to a respective one of a plurality of FIFO output control signals FIFO_OUT0 to FIFO_OUTm. The FIFO 262 can be implemented as a plurality of shift registers operated by a master clock CLK, for example. A person of ordinary skill in the art would be aware of a variety of ways to implement the FIFO 262, and accordingly the FIFO 262 is not described in detail. The FIFO output control signals FIFO_OUT0 to FIFO_OUTm are output from the control unit 270, and details thereof are described below.

The present disclosure comprises the count unit 263 that operates differently in a training period compared to in a normal operation period, and is activated during the training period to determine a transmission time of data transmitted from a selected bank of the DRAM chip 210 to a corresponding PE unit 260 of the logic die 250. This is a function block not present in the related art, and power consumption can be minimized by deactivating this function block during the normal operation.

The count unit 263 determines a data transmission time, which is the time from the time when a training read command COMP_RD_Train transmitted from the CTRL unit 270 to the DRAM chip 210 during the training period is activated to the time when RD_STROBE is asserted to indicate that data is being transmitted from the DRAM chip 210 to the logic chip 250 in response to the training read command COMP_RD_Train.

In terms of data transmission, when each bank is paired with a corresponding PE unit, the time, as measured from the issuance of a read command COMP_RD or a training read command COMP_RD_Train, for transmitting data from the plurality of banks to the plurality of PE units may be different for each pair for various reasons.

The CTRL unit 270 also distinguishes between the training period and the normal operation period, generating and utilizing the training read command COMP_RD_Train during the training period, and generating and utilizing a read command COMP_RD during the normal operation period. Details of the training read command COMP_RD_Train and the read command COMP_RD may be different from each other, but in embodiments the two commands may be the same.

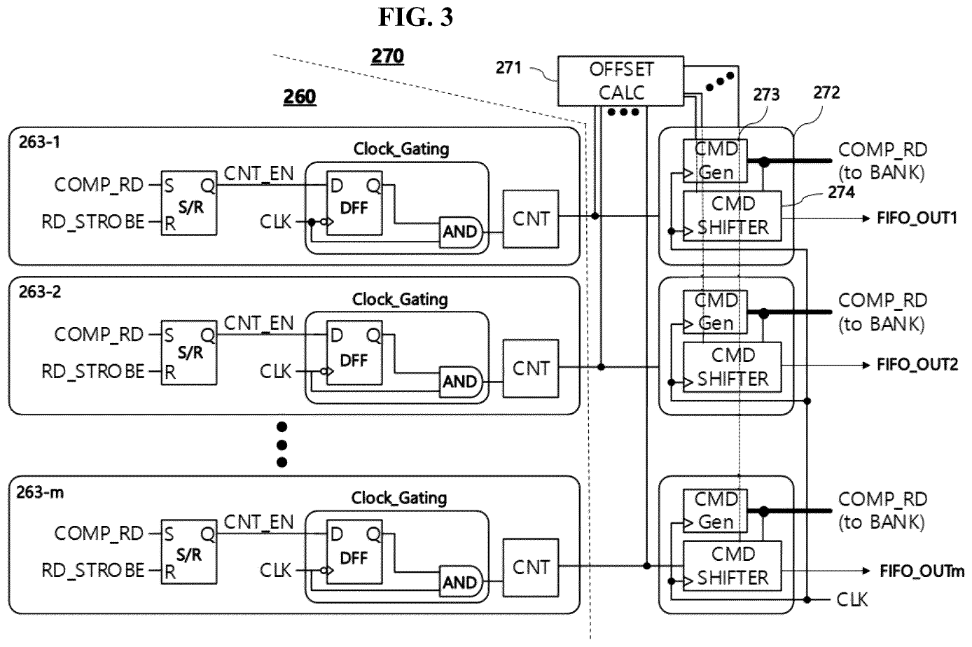

FIG. 3 illustrates an internal configuration of three instances of the count unit 263 of FIG. 2 (count units 263-1, 263-2, and 263-m), an offset corrector 271 (labeled OFFSET CALC), and three instances of a command generation unit 272.

In FIG. 3, elements on the left side of the dotted line illustrate components of the PE unit 260 and elements on the right side of the dotted line illustrate components of the control unit 270.

Referring to FIGS. 2 and 3, respective instances of the count unit 263 of the PE unit 260 may be installed in plural number m (m is a natural number) corresponding to the number of PE arrays 261, and since the instances are the same, the count unit 263-1 is described below.

Referring to FIG. 3, the count unit 263-1 includes a set/reset circuit S/R, a clock synchronization circuit Clock_Gating, and a counter CNT.

The set/reset circuit S/R generates a count enable signal CNT_EN in response to a read command COMP_RD supplied to a set terminal S and a read strobe signal RD_STROBE supplied to a reset terminal R. The read command COMP_RD may be asserted when either of a read command or a training read command is sent to the DRAM chip 210. The count enable signal CNT_EN enters a set state in response to the command COMP_RD supplied to the set terminal S is asserted and then maintains the set state until it transitions to a reset state in response to the read strobe signal RD_STROBE supplied to the reset terminal R is asserted. That is, because the count enable signal CNT_EN maintains the set state during the period between the time when the read command COMP_RD or the training read command COMP_RD_Train is activated and the time when data is actually output to the FIFO 262, and maintains the reset state otherwise, the period during which the count enable signal CNT_EN maintains the set state corresponds to the data transmission time.

The clock synchronization circuit Clock_Gating can be implemented with a D-type flip-flop DFF and an AND circuit. The D-type flip-flop DFF outputs a signal, which is obtained by delaying the count enable signal CNT_EN applied to an input terminal D by an inversion phase cycle of the master clock CLK, to a terminal Q, and the AND circuit ANDs the signal output from the D-type flip-flop DFF and the master clock CLK.

The counter CNT counts a signal output from the AND circuit of the clock synchronization circuit Clock_Gating. In embodiments, the counter CNY may be reset to 0 when the read command COMP_RD or the training read command COMP_RD_Train is activated. The time transmitted to a relevant PE array from a specific bank can be derived from the number of counts of the counter CNT.

Referring to FIG. 3, the control unit 270 includes an offset corrector (OFFSET CALC) 271 and a command generation unit 272.

The offset corrector 271 sets a reference transmission time by using a plurality of count signals according to a bank-specific path received from the counter CNT of the instances of the count unit 263 (e.g., count units 263-1 to 263-m of FIG. 3). Assuming that the offset corrector 271 collects m data transmission times from the counter CNT, the offset corrector 271 can set a maximum data transmission time among the m data transmission times as the reference transmission time, and reflect the reference transmission time in other transmission paths.

Since the maximum data transmission time with the longest transmission time is set as the reference transmission time, it becomes possible to set remaining data transmission times faster than the reference transmission time by using a relative value with respect to the reference transmission time. In the following description, the reference transmission time and a corrected transmission time reflecting the reference transmission time are assumed to be offset values.

The above description relates to setting the maximum data transmission time among the m data transmission times as the reference transmission time; however, an embodiment in which a minimum data transmission time or an average data transmission time is set as the reference transmission time may also be possible.

Referring to FIG. 3, the command generation unit 272 includes a command generator (CMD Gen) 273 and a command shifter (CMD SHIFTER) 274.

The command generator (CMD Gen) 273 generates the read command COMP_RD during the normal operation period in which normal data is transmitted, and generates the training read command COMP_RD_Train during the training period in which training data is transmitted.

During the training period, the training read command COMP_RD_Train is transmitted to the DRAM chip 210 and the command shifter (CMD SHIFTER) 274 in accordance with the master clock CLK, and during the normal operation period, the read command COMP_RD is transmitted to the DRAM chip 210 and the command shifter (CMD SHIFTER) 274 in accordance with the master clock CLK.

The DRAM chip 210 transmits data from the bank 220 to the PE unit 260 in response to the training read command COMP_RD_Train and in response to the read command COMP_RD.

In the present disclosure, in order to perform CDC smoothly, a training process is performed before performing a normal data transmission process so that a difference in data transmission time between a monitored bank and a PE unit pair, relative to a data transmission time between another bank/PE unit pair, can be corrected, and an offset value acquired in the training process is used to adjust the time at which data is output from the FIFO 262 to the PE array 261, thereby enabling smooth CDC between the two chips 210 and 250.

In the training process, the command generator (CMD Gen) 273 generates the training read command COMP_RD_Train, and in response to the training read command COMP_RD_Train, the offset corrector 271 monitors/corrects the time at which data is transmitted from the bank 220 of the DRAM chip 210 to the PE unit 260 of the logic chip 250 and generates offset information reflecting the corrected information.

Accordingly, in FIGS. 2 and 3, the count unit 263 and the offset corrector 271 may not be used in a normal data transmission process, and accordingly may be deactivated to save power during the normal data transmission process, and activated and used only in the training process.

The command shifter (CMD SHIFTER) 274 uses the read command COMP_RD received during the normal data transmission process and the offset information received from the offset corrector 271, and generates a FIFO output control signal (FIFO_OUT: FIFO_OUT1 to FIFO_OUTm) for determining the time at which the FIFO 262 outputs data.

Since the data transmission time between the bank and the PE unit is generally different for each bank, the FIFO output control signal FIFO_OUT may be different depending on the PE unit being supplied with the data.

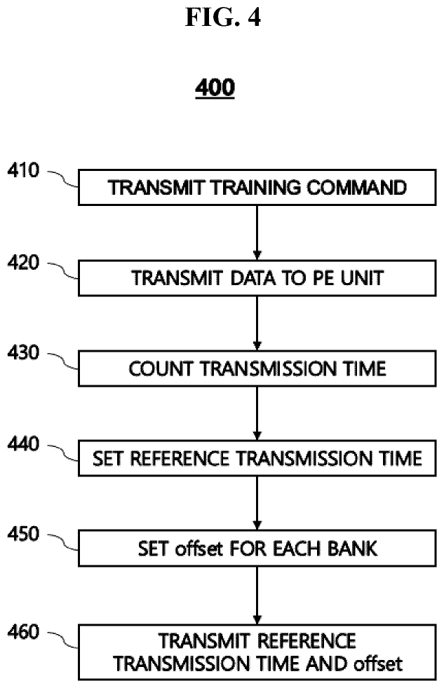

FIG. 4 illustrates a CDC training process 400 of the stacked PNM device according to an embodiment of the present disclosure.

The CDC training process 400 of the stacked PNM device according to the present disclosure includes step 410 in which the control unit 270 generates the training read command COMP_RD_Train and transmits the training read command COMP_RD_Train to the DRAM chip 210, step 420 in which the DRAM chip 210 transmits data stored in the bank 220 to the PE unit 260 in response to the training read command COMP_RD_Train, step 430 in which a count unit 263 or a plurality thereof constituting the PE unit 260 counts a transmission time for each bank, step 440 in which the offset corrector 271 constituting the control unit 270 receives the transmission time for each bank generated by the count unit 263 and sets the reference transmission time, step 450 in which the offset corrector 271 sets an offset value for each bank by using the reference transmission time and the transmission times for each bank, and step 460 in which the offset corrector 271 transmits the reference transmission time and the offset value for each bank to the command shifter 274.

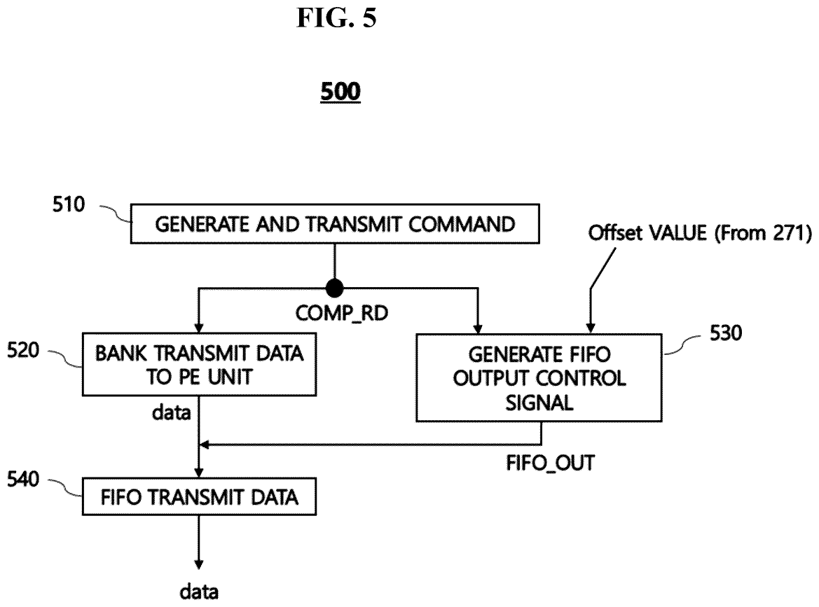

FIG. 5 illustrates an operating process 500 of the stacked PNM device CDC according to an embodiment of the present disclosure.

The operation process 500 of the stacked PNM CDC according to the present disclosure includes step 510 in which the control unit 270 generates the read command COMP_RD and transmits the read command COMP_RD to the DRAM chip 210, step 520 in which the DRAM chip 210 transmits data stored in the bank 220 to the PE unit 260 in response to the read command COMP_RD, step 530 in which the command shifter 274 generates a FIFO output control signal FIFO_OUT for each bank by using the reference transmission time and the offset value for each bank received from the offset corrector 271, and step 540 in which the FIFO 262 transmits data received from the bank 220 to the PE array 261 in response to the FIFO output control signal FIFO_OUT for each bank.

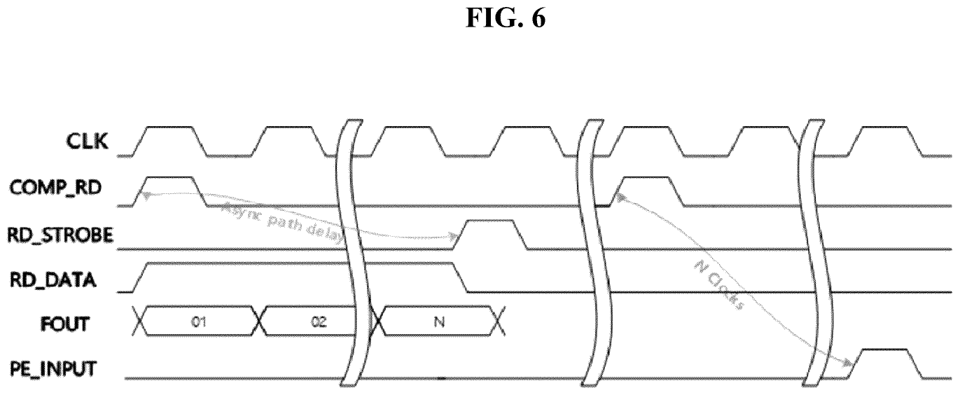

FIG. 6 is a timing diagram of the stacked PNM device according to the present disclosure.

Referring to FIG. 6, it can be seen that the stacked PNM device 200 according to the present disclosure smoothly performs CDC in an asynchronous path section (Async path delay) in which data is transmitted from the bank 220 of the DRAM chip 210 to the PE unit 260 of the logic chip 250 and a synchronous section (N Clocks) in which data received from the DRAM chip 210 is processed.

Although the technical essence of the present disclosure has been described together with the accompanying drawings, this is an illustrative example of an embodiment of the present disclosure, and does not limit the present disclosure. In addition, it is clear that various modifications and imitations can be made by a person skilled in the art to which the present disclosure belongs without departing from the scope of the technical essence of the present disclosure.

What is claimed is:

1. A stacked Processing Near Memory (PNM) device comprising:
a memory chip comprising a plurality of banks configured to transmit stored data in response to a training read command and in response to a read command; and
a logic chip comprising:
a processing element (PE) unit configured to receive the data from the memory chip and process the received data,
and a control unit configured to generate the training read command and the read command,
wherein the memory chip and the logic chip are stacked and electrically connected to each other,
wherein the PE unit comprises:
a PE array comprising a plurality of processing elements;
a First-In-First-Out queue (FIFO) configured to store the data received from the DRAM chip and transmit the stored data to the PE array in response to a FIFO output control signal; and
a count unit configured to count a time for which data of the DRAM chip is transmitted to the FIFO for each bank, and
wherein the control unit comprises:
an offset corrector configured to generate an offset for each bank by using a count value output from the count unit; and
a command generation unit comprising a command generator configured to generate the training read command during a training period and generate the read command during a normal operation period, and a command shifter configured to generate the FIFO output control signal by using the offset.

2. The stacked PNM device of claim 1, wherein the count unit and the offset corrector are activated during the training period and are deactivated during the normal operation period.

3. The stacked PNM device of claim 1, wherein the count unit comprises:
a set/reset circuit configured to generate a count enable signal in response to the training read command applied to a set terminal and a read strobe signal applied to a reset terminal;
a clock synchronization circuit comprising a D-type flip-flop configured to output a signal, which is obtained by delaying the count enable signal applied to an input terminal by an inversion phase cycle of a master clock, to a terminal Q, and an AND circuit configured to AND the signal output from the D-type flip-flop and the master clock; and
a counter configured to count a signal output from the AND circuit,
wherein the read strobe signal is activated at a moment when the data is output from the memory chip.

4. The stacked PNM device of claim 1, wherein the offset corrector sets a reference transmission time by using a plurality of count values output from the count unit and generates the offset by using the reference transmission time, and
the reference transmission time corresponds to a maximum value of the plurality of count values, a minimum value of the plurality of count values, or an average value of the plurality of count values, and
the offset reflects a difference from the reference transmission time for each bank.

5. A clock domain crossing (CDC) training method of a stacked Processing Near Memory (PNM) device, the CDC training comprising:
generating, by a control unit, a training read command and transmits the training read command to a memory chip comprising a plurality of banks;
transmitting, by the memory chip, data stored in the plurality of banks to a PE unit in response to the training read command;
counting, by a count unit constituting the PE unit, a transmission time for each bank;
receiving, by an offset corrector constituting a control unit, the transmission time generated by the count unit and setting a reference transmission time; and
setting, by the offset corrector, an offset value for each bank by using the reference transmission time.

6. The CDC training method of claim 5, wherein the reference transmission time corresponds to a maximum value among a plurality of count values received by the offset corrector from the count unit, a minimum value among the plurality of count values, or an average value among the plurality of count values r, and
the offset reflects a difference from the reference transmission time for each bank.

7. The CDC training method of claim 6, further comprising:
transmitting, by the offset corrector, the reference transmission time and the offset value to a command shifter included in the control unit.

8. A normal operation method of a stacked Processing Near Memory (PNM) device, the normal operation method comprising:
generating, by a control unit, a read command and transmitting the read command to a memory chip comprising a plurality of banks;
transmitting, by the memory chip, data stored in the plurality of banks to a PE unit constituting a logic chip in response to the read command;
generating, by a command shifter, a First-In-First-Out queue (FIFO) output control signal for each bank by using a reference transmission time and an offset value for each bank received from an offset corrector; and
transmitting, by a FIFO, data received from the bank to a PE array in response to the FIFO output control signal for each bank.

9. The normal operation method of claim 8, wherein the offset value is generated during a training period before the PNM performs a normal operation, and is generated by collecting and processing a data transmission time for each bank from a time when a training read command is activated until the DRAM chip transmits data to the logic chip according to the training read command.

10. The normal operation method of claim 9, wherein a reference transmission time is set using the collected data transmission time for each bank, and the offset value is set using the reference transmission time.

11. The normal operation method of claim 10, wherein the reference transmission time corresponds to a maximum value among a plurality of count values corresponding to received data transmission times for each bank, a minimum value among the plurality of count values, or an average value among the plurality of count values, and
the offset reflects a difference from the reference transmission time for each bank.
